(19) United States
(12) Patent Application Publication
(10) Pub. No.: US 2025/0237821 A1
(43) Pub. Date: Jul. 24, 2025

(54) OPTICAL PHASED ARRAY, LASER ASSEMBLY AND METHOD FOR OPERATING SAME

(71) Applicant: ams-OSRAM International GmbH, Regensburg (DE)

(72) Inventors: Georg ROSSBACH, Wenzenbach (DE); Christoph SCHMID, Wald (DE); Christian SCHOERNER, Regensburg (DE)

(73) Assignee: ams-OSRAM International GmbH, Regensburg (DE)

(21) Appl. No.: 18/855,462

(22) PCT Filed: Apr. 13, 2023
(86) PCT No.: PCT/EP2023/059736

§ 371 Date: Oct. 9, 2024

(30) Foreign Application Priority Data
Apr. 14, 2022 (DE) 10 2022 109 220.8

(51) Int. Cl. G02B 6/42

(52) U.S. Cl. CPC G02B 6/4214

(57) ABSTRACT

The invention relates to an optical phase array with a signal input for supplying use light of a first wavelength and a first modulation input for supplying modulation light of a second wavelength. A first waveguide array with at least one signal output is connected to the signal input and comprises a material transparent to the use light and having a first bandgap. A second waveguide array connected to the first modulation input is arranged and designed in the vicinity of the first waveguide array in such a way as to guide modulation light onto the first waveguide array, the first band gap being smaller than the energy of the modulation light.

### CROSS-REFERENCE TO RELATED APPLICATIONS

The present invention is a national stage entry from International Application No. PCT/EP2023/059736, filed on Apr. 13, 2023, published as International Publication No. WO 2023/198865 A1 on Oct. 19, 2023, and claims the priority of the German first application DE 10 2022 109 220.8 filed Apr. 14, 2022, the disclosures of all of which are hereby incorporated by reference in their entireties.

### FIELD

The present invention relates to an optical phase array, a resonator assembly and a laser arrangement with the optical phase array or the resonator assembly. The invention also relates to a method for operating an optical phase array or a resonator assembly.

### BACKGROUND

Edge-emitting lasers are based on laser diodes and are now available for a broad frequency spectrum. Their high output power and realization as a mass product have made them interesting for a variety of applications. In addition to edge-emitting lasers, VCSELs or uLEDs with a small etendue can also be used to couple the light into a waveguide. These are generally referred to as optoelectronic components.

Such optoelectronic components are characterized by a larger line width in the range of a few nanometers, whereby the output frequency also varies depending on the current and the temperature. Although this opens up the possibility of tuning, it also influences the output power of the laser and requires more circuitry to compensate for or suppress undesirable effects.

In a number of applications, however, lasers with a narrow line width or high stability of the emission wavelength and power are desired. To achieve this, it is necessary to stabilize edge-emitting lasers. On the one hand, this can be achieved using DBR structures along the laser resonator, although this is associated with increased costs. An alternative is to couple the laser arrays with external cavities with adjustable etalons, Bragg gratings or even microresonators with a small form factor. With all of these, linewidths of just a few kHz can be achieved.

In other applications, the focus is on the ability to align a light beam, i.e. to cover a defined field of view with a previously defined resolution. Examples of such applications include RGB projections as well as LIDAR. This can be realized with a component that expands the laser beam in order to cover a high-resolution LCD, SLM (Spatial Light Modulator) or DLP display. Alternatively, a laser beam or a light beam can be deflected using movable mirrors, either as MEMS or even macromechanical types. Neither technique is an ideal compromise: Pixel array projections comprise lower efficiency and lack contrast and brilliance, while mechanically moving elements often lead to robustness issues and increased complexity.

There is therefore a need for non-mechanical beam control or sensing options that can be easily integrated into a housing and thus enable a significant reduction in construction volume.

### SUMMARY OF THE INVENTION

This need is met by the objects of the independent patent claims. Further developments and embodiments of the proposed principle are given in the sub-claims.

To this end, the inventors propose optical phased arrays (OPAs), which are optically controlled and enable large modulation bandwidths on very small form factors. In addition to optical phase arrays, the proposed principle can also be used to control other optical components such as resonators, modulators or even optical switches in a very fast and wear-free manner.

In particular, in an optical component of the type mentioned above, the inventors make use of the fact that the refractive index can be influenced by free charge carriers, among other things. For example, an optical component can comprise a transparent semiconductor material in which free charge carriers are generated by absorbing photons with higher energy than the band gap. These photons are provided via a so-called modulation light. The photon flux is the basis for active modulation of the optical component and can be provided, for example, by a second planar waveguide component located below and/or above it, which directs the modulation light onto the optical component to be modulated.

This results in a modulation of the refractive index, whereby the modulation speed is essentially limited by the lifetime of the charge carriers in the material. Particularly in the case of optical phase arrays in the narrower sense, this provides a waveguide ensemble that is tailored to the desired phase shift function. A high-frequency intensity-modulated control laser or a laser diode (or possibly several of them) provides the required photon flux.

In some aspects of the principle presented here, an optical phase array is proposed. The term “optical phase array” should not be understood in a narrow sense. Rather, it refers to a component whose optical behavior can be adjusted in a desired manner by changing the refractive index. The change in the refractive index is achieved by a further element of the phase array, which deflects a modulation light so that it generates charge carriers by absorption, which change the refractive index. Possible such components, whose refractive index is advantageously adjustable, include optical phase arrays in the narrow sense, i.e. with several waveguides of different lengths, optical resonators, in particular ring oscillators, Mach-Zehnder modulators or even directional optical couplers, to name but a few.

The adjustable optical phase array comprises a signal input for supplying use light of a first wavelength and a first modulation input for supplying modulation light of a second wavelength. A first waveguide array is connected to the signal input and comprises at least one signal output and a material that is transparent to the use light and comprises a first band gap. A second waveguide array is connected to the first modulation input and arranged in the vicinity of the first waveguide array in such a way that modulation light can be conducted to the first waveguide array. The first band gap is smaller than the photon energy of the modulation light. In other words, the material of the first waveguide array is selected so that it absorbs light of the second wavelength, forming charge carriers. The term waveguide array is also not to be understood excessively narrowly in the broader understanding of an optical phase array mentioned above, but rather as an optical component that is intended to provide a certain functionality.

In this context, the first and second waveguide arrays can comprise the same or at least a similar shape. In particular, the second waveguide array should be designed such that it can deflect the modulation light well onto the first waveguide array, i.e. the first component whose refractive index is to be changed. Accordingly, in some aspects it is provided that the first waveguide array and the second waveguide array are arranged one above the other in two substantially parallel planes and additionally overlap in some areas. The overlap increases the efficiency, as the modulation light can radiate better into the first waveguide array. The waveguides of the second waveguide array are matched to the first waveguide array so that the desired refractive index change occurs in the individual waveguides of the first array at a predetermined intensity of the modulation light.

The intensity of the modulation light can be used to adjust the rate of charge carrier generation and thus modulate the refractive index in the first waveguide array. The modulation can be digital, e.g. using a pulsed modulation signal, but also as an amplitude-modulated signal.

In some aspects, the first waveguide array of the optical phase array comprises a plurality of waveguides that lie substantially in a plane and comprise a defined time-of-flight difference with respect to each other. This can be realized, for example, by a different length of the waveguides. The time-of-flight difference results in a phase difference at the output of the array and thus a superposition and therefore interference. By modulating the refractive index according to the proposed principle, the phase difference can be controlled so that a light beam emitted by the array can be controlled.

In a further aspect, the second waveguide array also comprises a plurality of waveguides that lie essentially in one plane and comprise a defined time-of-flight difference to one another. This can also be implemented with waveguides of different lengths.

In a further aspect, the optical phase array comprises a further second modulation input for supplying modulation light of the second or a third wavelength. The modulation light of the third wavelength is also more energetic than the band gap of the material of the first waveguide array, so that absorption occurs with the generation of free charge carriers. The second modulation input is connected to a third waveguide array and arranged in the vicinity of the first waveguide array in such a way that modulation light can be conducted to the first waveguide array. In this way, increased flexibility is achieved and the range of refractive index modulation is also increased by generating charge carriers. At this point, it is possible to arrange the first waveguide array between the second and third waveguide arrays and thus direct modulation light from both sides onto the first waveguide array. Depending on the configuration, the second and third waveguide arrays can either overlap or be arranged as mirror images of each other.

In a further aspect, the second and/or third waveguide array comprises a decoupling structure, in particular in the form of diffractive optics. This is used to couple the modulation light out of the waveguide array in a defined manner. The diffractive optics or the decoupling structure can also act as a light guide and thus guide the modulation light onto the first waveguide. In some embodiments, the output coupling structure faces the first waveguide array. The decoupling structure makes it possible to locally decouple a definable portion of the modulation light. In an alternative embodiment, the second and/or third waveguide array are only slightly spaced from the first waveguide array, for example less than 300 nm and in particular less than 100 nm. As a result, part of the light (part of the light field) reaches the first waveguide array as evanescent light. For example, the waveguide arrays can also be so close together that crosstalk of the modulation light into the first waveguide array occurs.

Another aspect is concerned with improving the light coupling of the modulation light into the first waveguide array. In one aspect, a particularly planar DBR structure is provided, which is arranged on the side of the first waveguide array opposite the second waveguide, in particular for back-reflection of modulation light. This allows modulation light to be either absorbed or reflected back. In a further embodiment, it is conceivable to provide a planar distribution layer which is arranged on the side of the first waveguide opposite the second waveguide and is designed to reflect back modulation light or to distribute charge carriers generated by modulation light in the first waveguide array. A uniform distribution of the charge carriers is useful in order to generate a uniform refractive index change.

Some aspects deal with a suitable choice of material. In some aspects, a semiconductor material is used as the material of the first waveguide array. This may have a direct bandgap or an indirect bandgap, but is selected to be substantially transparent to the useful light. In one aspect, the material comprises InP, Si, GaAs, AlGaAs, AlGaP or GaN. However, these materials are not transparent to the light of the second wavelength; the modulation light is therefore absorbed, generating charge carriers in the material. However, the material of the second or even the third waveguide array should be transparent to the modulation light. This means that it generally comprises a higher band gap than the material of the first waveguide array. Possible materials that can also be matched to the material of the first waveguide array would be AlN, SiNx, Al2O3 or even SiO2.

In some aspects, a resonator assembly is proposed comprising a waveguide having a signal input for supplying use light of a first wavelength and a signal output. The arrangement further comprises a resonator, in particular a ring resonator, which is optically coupled to the waveguide in order to amplify a frequency mode of the use light in the waveguide. An arrangement is placed above the resonator which is designed to radiate modulation light of a second wavelength into the resonator. For this purpose, the resonator is formed with a material with a band gap that is essentially transparent for use light and absorbs modulation light by forming charge carriers. In this way, a tunable resonator assembly is implemented that enables a particularly mode-stable but tunable laser. Possible applications for such resonator assemblies are in the field of coherent distance measurement, high-resolution spectroscopy or image projection, for example for AR or VR projections.

In one embodiment, the arrangement placed above the resonator comprises one or more deflecting mirrors. Alternatively, the arrangement can also comprise a second waveguide with diffractive optics, which is designed to direct modulation light in the second waveguide onto the resonator. As with the optical phase array, a planar DBR structure in particular can be provided, which is arranged on the side of the resonator opposite the second waveguide, in particular for back-reflection of modulation light.

A further aspect relates to a laser arrangement that uses optical components according to the proposed principle. The laser arrangement comprises a first laser device for generating use light and a second laser device for generating modulation light. The intensity of the modulation light is modulated by the second laser device. The two laser devices are connected to the optical phase array, the optical component or the resonator assembly.

A further aspect relates to an operation of an optical phase array, wherein the phase array comprises a signal input for supplying use light of a first wavelength and a first waveguide array with at least one signal output, which is connected to the signal input and comprises a material transparent to the use light with a first band gap. In the method, use light is irradiated into the first waveguide array. A modulation light is also generated and at least partially coupled into the first waveguide array. By absorbing the irradiated modulation light, charge carriers are generated in the first waveguide array, which change the refractive index in a characteristic manner. The change in the refractive index is controlled by varying the intensity of the modulation light.

In one aspect, the modulation light is coupled in by means of a second waveguide array, which is arranged in the vicinity of the first waveguide array in such a way that modulation light can be guided onto the first waveguide array. Depending on the optical component, the first and second waveguide arrays comprise different properties and characteristics. In some aspects, the first waveguide array comprises a plurality of waveguides that lie substantially in a plane and comprise a defined time-of-flight difference with respect to each other. In the same way, the second waveguide array may also be designed and comprise a plurality of waveguides that lie substantially in a plane and comprise a defined time-of-flight difference with respect to each other. In some embodiments, the time-of-flight differences in the waveguides of the first or second waveguide array are formed by different lengths of the waveguides.

### BRIEF DESCRIPTION OF THE DRAWINGS

Further aspects and embodiments according to the proposed principle will become apparent with reference to the various embodiments and examples described in detail in connection with the accompanying drawings.

FIG. 1 shows a configuration of an optical phase array;

FIG. 2 shows a top view of a design of a phase array according to the proposed principle;

FIG. 3 is a sectional view of the phase array shown in FIG. 2 with some aspects of the proposed principle;

FIG. 4 shows a second embodiment of an optical phase array with some aspects of the proposed principle;

FIG. 5 is an alternative version of FIG. 4;

FIG. 6 shows the sectional view of the phase array according to FIG. 4 or 5 to explain some aspects of the proposed principle;

FIG. 7 shows a sectional view of a further embodiment of a phase array according to the proposed principle;

FIG. 8 shows a further sectional view of an embodiment of a phase array according to the proposed principle;

FIG. 9 is a third embodiment of a phase array with some aspects of the proposed principle;

FIGS. 10 to 12 are different sectional views of versions of a phase array according to the principle of FIG. 9;

FIG. 13 is an embodiment of a process with some aspects of the proposed principle.

### DETAILED DESCRIPTION

The following embodiments and examples show various aspects and their combinations according to the proposed principle. The embodiments and examples are not always to scale. Likewise, various elements may be shown enlarged or reduced in size in order to emphasize individual aspects. It is understood that the individual aspects and features of the embodiments and examples shown in the figures can be readily combined with each other without affecting the principle of the invention. Some aspects concern a regular structure or shape. It should be noted that slight deviations from the ideal shape may occur in practice without, however, contradicting the inventive concept.

In addition, the individual figures, features and aspects are not necessarily shown in the correct size, and the proportions between the individual elements are not necessarily correct. Some aspects and features are emphasized by enlarging them. However, terms such as “above”, “above”, “below”, “below”, “larger”, “smaller” and the like are shown correctly in relation to the elements in the figures. It is thus possible to deduce such relationships between the elements on the basis of the figures.

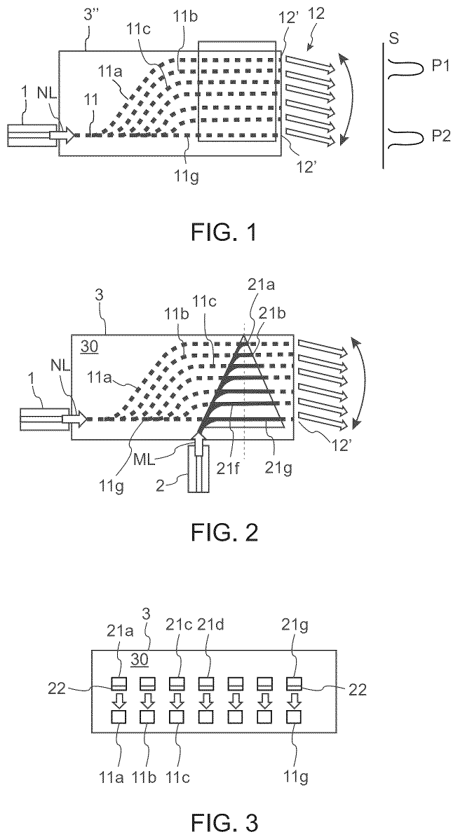

FIG. 1 shows the arrangement of a so-called optical phase array in the narrower sense, i.e. an arrangement in which beam shaping can be achieved by means of a phase offset generated by several optical fibers of different lengths.

The arrangement comprises an edge-emitting laser 1, for example in the form of a laser diode, or alternatively another laser arrangement. An optical phase array 3″ is connected to the output of this laser arrangement. This comprises a waveguide 11 connected to the signal input, which then splits into several individual branches 11a, 11b to 11g. Each of these individual branches comprises a different length and leads to a corresponding signal output 12′.

In one operation of the arrangement, use light NL is emitted and distributed into the various branches 11a to 11g of the optical phase array 3″. Due to the different lengths of the individual branches, this leads to signals with a phase offset at the respective outputs 12′. These signals interfere with each other. By setting the length appropriately based on the frequency or wavelength of the scattered useful light, this leads to constructive or destructive interference. The position of the constructive interference on a screen S at positions P1 and P2, shown as an example in FIG. 1, can be adjusted by various means. In general, the position of this constructive interference depends on the geometric parameters and the refractive index of the waveguides 11a to 11g. By changing the refractive index of the material, the position P1 or P2 on the screen S can be controlled so that a “scanning” of the screen is achieved by means of the interfering output light.

Conventional methods use, for example, a thermal process in which the optical phase array 3″ is heated or cooled, causing the respective refractive index of the waveguides to change in a characteristic manner. However, such a process is relatively slow and can only be controlled to a limited extent. Alternatively, it is also possible to change the refractive index in the individual areas by applying a constant electric field. Although this leads to an improvement compared to a thermal process, it requires relatively high voltages to generate the necessary electric field. Especially for applications with low available operating voltages, such an approach is therefore rather complex to implement.

FIG. 2 shows an embodiment of the proposed principle in which the refractive index of the optical component is not adjusted using a thermal or electro-optical process, but by means of a purely optical process. This takes advantage of the fact that the material of the waveguides 11a to 11g, i.e. the material of the optical component 3, also comprises a band gap and can therefore also absorb light. Although the waveguides 11a to 11g are transparent to the useful light, photons of higher energy can be absorbed in the waveguides and thus generate free charge carriers. These free charge carriers then cause a change in the refractive index in a characteristic manner. FIG. 2 now shows a possible embodiment of this principle.

The arrangement according to the proposed principle comprises an optical component 3, which in the present case is also designed as an optical phase array in the narrower sense. A laser device 1 is arranged at a signal input, which in turn is coupled to a waveguide 11. This can be an edge-emitting laser, a laser diode or a laser device not based on semiconductor structures. The optical phase array comprises a large number of waveguides 11a, 11b to 11g, which are connected to each other on the input side and each lead to a signal output 12′ on the output side. The length of the respective waveguides between the signal input and signal output is different and matched to each other in such a way that an interference pattern of irradiated light is produced at the output on a screen in a similar way to that shown in FIG. 1.

According to the invention, the optical component 3 now comprises a second signal input, which in turn is connected to a second laser diode 2 for supplying a modulation light ML. This modulation input is in turn connected to a plurality of waveguides 21a, 21b to 21g. The waveguides also form a waveguide structure for the modulation light ML and are designed in such a way that the individual waveguides 21a, 21b to 21g are located above a part of the waveguides 11a, 11b to 11g.

FIG. 3 shows a sectional view of the arrangement according to the proposed principle. It can be seen here that the individual waveguides 11a, 11b to 11g for the use light NL are arranged essentially along a plane. Above this plane, also in one plane, the waveguide structures 21a, 21b to 21g for the modulation light ML are again provided. Each of these waveguides 21a, 21b to 21g of the structure for the modulation light ML comprises a decoupling optic 22, which faces the respective waveguide 11a, 11b to 11g.

In one operation of the proposed arrangement, a modulation light ML is irradiated whose photon energy is greater than the band gap of the material in the waveguides 11a, 11b to 11g. For the sake of simplicity, it is assumed here and in the following for the explanation of the principle according to the invention that the band gap is constant and that it makes no difference with regard to crystal direction or direct/indirect band gap. In fact, the present principle is possible if light is absorbed in the material of the waveguide or in the surrounding area, which then generates free charge carriers in the material of the waveguide.

The modulation light ML exits through the existing decoupling optics and is optically absorbed by the waveguides 11a, 11b to 11g. The absorption generates charge carriers in the conduction band of the material of the waveguides 11a, 11b to 11g, which changes the refractive index of this material. The length of the individual waveguides 21a, 21b to 21g for the modulation light ML, shown in plan view in FIG. 2, results in an intensity-dependent irradiation and also a resulting absorption in a predetermined manner, so that a characteristic refractive index change occurs in the individual waveguides 11a, 11b to 11g for the use light NL. Changing the intensity of the modulation light ML also changes the refractive index. An intensity modulation of the light ML thus causes a modulation of the refractive index in a characteristic manner.

The material of the waveguides for the modulation light ML is selected in such a way that it is transparent to the modulation light ML itself. However, the energy of the photons of the modulation light ML is so high that it exceeds the band gap of the waveguides 11a to 11g and is thus absorbed by them, generating free charge carriers. By adjusting the intensity of the modulation light, the generation of charge carriers and thus also the resulting refractive index change can be adjusted or changed. In this way, it is possible to adjust the interference pattern at the output of the optical component 3 and, for example, to achieve the effect shown in FIG. 1 of changing a constructive interference maximum along a position.

The change in refractive index based on charge carriers is essentially determined by three effects. On the one hand, this is a filling of the density of states or filling of the permitted band states with free charge carriers according to Burstein Moss, which generally leads to a refractive index change to lower values. However, a band gap normalization or even a slight change in the band gap towards lower energies leads to a refractive index change towards higher values. Finally, a free charge carrier generation and subsequent characteristic absorption in the IR range can also be used to change the refractive index in the interesting transparency range of the EM spectrum to lower values. In the proposed principle, these three aspects work together, with the free charge carrier absorption according to the Drude model being the main aspect.

Charge carriers absorb a light particle in the medium, which raises them to a higher energy state. Charge carriers within the valence band are raised to the conduction band, forming an electron-hole pair. In this way, free-moving electrons are generated in the conduction band, which act similarly to an e-h plasma. This plasma generates a characteristic absorption band in the IR range, which can be described using the Drude model. Via the so-called Kramers-Kronig relation, this in turn produces a lowering of the refractive index at shorter wavelengths. According to the Drude model, shown in formula (1)

$$Δ n = - ( \frac{{e}^{2} {λ}^{2}}{8 {π}^{2} {c}^{2} {ε}_{0} n} ) ( \frac{N}{{m}_{e}} + \frac{P}{{m}_{h}} ) \qquad ( 1 )$$

this results in a refractive index change that essentially depends on the number of negative electrons in the conduction band or holes in the valence band. The values N and P are the respective free charge carriers, the masses m denote the respective effective masses of the electrons or holes, although the mass mx of the holes is significantly greater than the mass of the electrons, so that the term P/mₕ is often negligible.

The refractive index change is negative, i.e. the refractive index is reduced by the absorption of light within the waveguide. In addition, the refractive index change is proportional to the square of the wavelength λ which generally results in a higher refractive index change at longer wavelengths, i.e. at lower energies.

In the following, the generation of charge carriers with an irradiated modulation light is to be estimated and the resulting change in the refractive index is to be understood, at least qualitatively. In this estimation, the modulation light is generated by a laser with a power of 100 mW and a beam diameter of d=100 μm. The wavelength of the modulation light is λ=400 nm. A combination of InP and GaP is used as the waveguide material for the optical component; the parameters used refer to InP. With InP, the refractive index at λ=400 nm is equal to n=4.4, whereas GaP comprises a refractive index of n=4.2 at λ=400 nm. The intensity I is then

$$I = \frac{P}{π * {( \frac{d}{2} )}^{2}} \qquad ( 2 )$$

In simplified terms, it is assumed that the modulation light is absorbed completely in the material, essentially without reflection or loss.

The intensity of the laser beam decreases exponentially within the material, i.e. the intensity is roughly proportional to e^{(-z/z0)}, where z₀ is the absorption length. The absorption length corresponds to the length z at which the intensity of the light has dropped to 1/e (or here 1/e² for I) of the original I. This results in an approximate absorption length of

$$I ( {z}_{0} ) = \frac{{I}_{0}}{{e}^{2}} with {z}_{0} approx . 40 nm$$

The decrease in light means that charge carriers have been generated there. In this way, the number of charge carriers can be estimated in the absorption length with

$${n}_{inj} = \frac{I - I ( {z}_{0} )}{{z}_{0} h v} = 6 * 1 {0}^{26} \frac{1}{{cm}^{3} {s}^{◻}} \qquad ( 3 )$$

This is therefore in the range of around 10²⁶ 1/(scm³). With an irradiation time of around 1 ns, this produces

$${n}_{inj} = 6 * 1 {0}^{17} \frac{1}{{cm}^{3}}$$

are generated.

However, the electron-hole plasma generated in this way also recombines again, causing the number of free charge carriers to decrease. The recombination rate follows various mechanisms. On the one hand, these mechanisms are recombination by means of direct recombination, i.e. the electron and hole recombine together to produce a corresponding photon, plasmon or phonon. Alternatively, there is also the possibility of so-called Auger recombination, which, however, is several orders of magnitude lower than direct recombination and can therefore be disregarded in the analysis.

The recombination rate R thus results from the concentration n, p of the available charge carriers and a material-dependent parameter C, which characterizes the two above-mentioned mechanisms in the respective material.

$$R = C * ( n * p - {n}_{i}^{2} ) \qquad ( 4 )$$

For an indexed charge carrier density n=p in the range of 6×10¹⁷ 1/cm³ and a parameter C of 6*10⁻¹¹ cm³/s, which indicates the direct recombination, a recombination rate R in the range of 2×10¹⁶ 1/nscm³ follows from equation (4). With a roughly constant recombination rate, the generated charge carriers would therefore be completely combined after approx. 10 ns.

The generation rate of the charge carriers and the recombination rate can also be represented using a differential equation, which is given in equation (5). The generation rate ∂n(t)/∂t at thus corresponds to a constant value given by a parameter α which corresponds to the charge carrier density and can be derived from (3) and the intensity I, which is minus the product of the recombination rate and the number of charge carriers over time. The following applies:

$$\frac{\partial n ( t )}{\partial t} = α I - {Cn ( t )}^{2} with the initial condition n ( 0 ) = 0 \qquad ( 5 )$$

The solution to this differential equation is a function increasing at 0 over time, which reaches equilibrium after approx. 15 ns. With a continuously irradiated modulation light or a modulation of the intensity of the irradiated modulation light whose frequency is significantly lower than the recombination rate, an equilibrium is established between the generation of charge carriers and the recombination. The intensity at equilibrium essentially corresponds to the square root of the indexed charge carriers due to the recombination:

$$\sqrt{\frac{{n}_{inj}}{C}}$$

For the example of a laser with the above-mentioned power, a charge carrier density in the range of a few 10¹⁸ 1/cm³ results at equilibrium.

From the above-mentioned differential equation and the estimates regarding the irradiated modulation light and the other parameters, a charge carrier concentration in the range of 10¹⁷ to 10¹⁹ charge carriers per cm³ can be generated. From this, a refractive index change according to the Drude model in the range of 10⁻², i.e. in the range of a few percent, can be estimated. Higher intensities of modulation light increase the absorption within the material and thus the charge carrier concentration, which also increases the refractive index change.

For example, in order to achieve a phase change of π between two waveguides due to a change in the refractive index, it is therefore sufficient to provide a waveguide with a length of approx. 100 μm and to generate a charge carrier density in the range from 10¹⁸ to approx. 10¹⁹ in this waveguide. It follows that with an additional modulation light, either by a single additional laser or also by several lasers, a sufficient charge carrier concentration of free charge carriers can be generated within the material of the optical component in order to produce the necessary refractive index change for a phase shift of 180°. π can be generated.

Following this principle, various designs for optical components can be implemented in which charge carriers are formed in a part of the optical component by means of a supply of high-energy light, so that the refractive index changes.

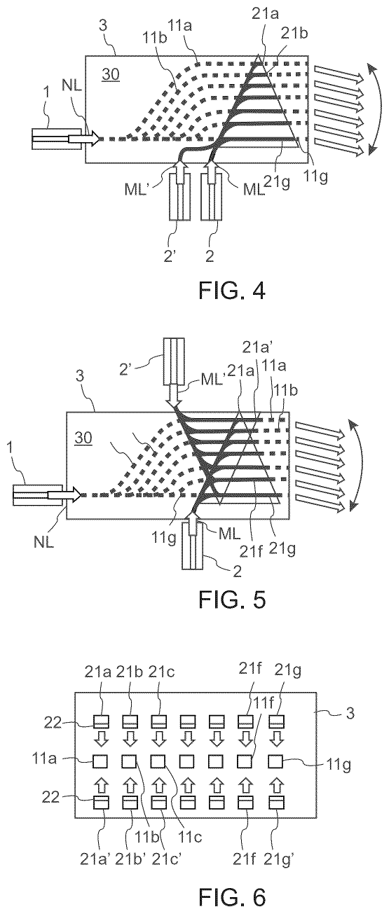

FIG. 4 shows a further embodiment in which greater flexibility in setting the refractive index can be achieved by means of several additional laser devices for generating modulation light ML, possibly also of different wavelengths. In addition, such a configuration also allows a certain symmetrical shape, so that a more uniform charge carrier distribution is achieved.

FIG. 4 shows an optical component 3. A laser device 1 for supplying the use light NL is again connected to the signal input. In this design example, two laser devices 2 and 2′ are provided, each of which supplies a modulation light ML and ML′ to the two additional modulation inputs of the optical component 3. The waveguide structure, connected to the modulation inputs, is designed in the same way and is shown in cross-section in FIG. 6 as an example.

It can again be seen here that the first waveguide structure with the waveguides 11a, 11b to 11g is arranged in one plane. In contrast, the two waveguide structures with the branches 21a, 21b to 21g for the modulation light ML and 21a′, 21b′ to 21g′ for the modulation light ML′ are arranged above or below the first waveguide structure. In other words, the waveguides 11a, 11b to 11g are surrounded on both sides by a corresponding modulation waveguide structure. When the modulation light ML is switched on, here indicated by the arrows in FIG. 6, the light is thus guided by the decoupling structure 22 onto the first waveguide structure in as uniform a manner as possible. As a result, a more uniform distribution of the scattered modulation light ML into the waveguide structure with the waveguides 11a, 11b to 11g is achieved, which in turn leads to a more uniform charge carrier distribution. In addition, in this embodiment example, a significantly larger refractive index jump can be achieved depending on the degree of absorption, as the intensity can be adjusted over a larger range due to the possible higher intensity with the waveguides 21a′, 21b′ to 21g′.

FIG. 5 shows a modification in this respect, in which the waveguide structures for the modulation light ML or for the modulation light ML′ are provided with mirror symmetry above or below the waveguide structure for the use light NL. This means that the length of the individual waveguides 21a, 21b to 21g or 21a′, 21b′ to 21g′ above or below the respective waveguides 11a, 11b to 11g is different. This provides a degree of freedom in setting the interference pattern and the refractive index change.

A further alternative embodiment is to provide additional mirrors or other optical or electro-optical structures above or below the waveguide structure for the useful light. These can be used to generate a more uniform light distribution or a more uniform charge carrier distribution, which ultimately improves the signal quality.

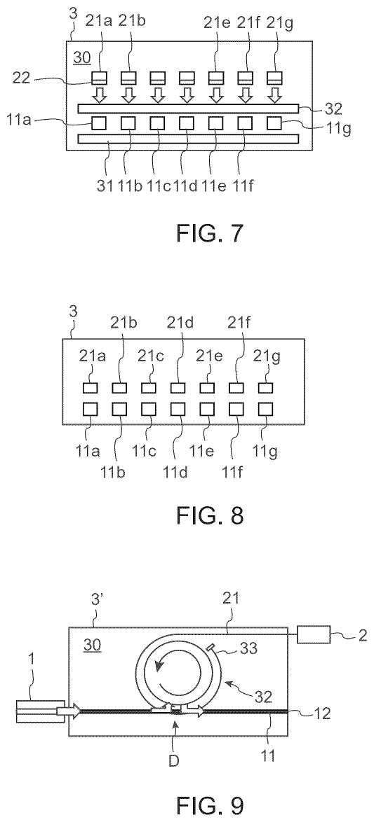

FIG. 7 shows an embodiment example in cross-section, in which two additional DBR structures 31 and 31′ are arranged above and below the plane of the waveguide structure for the use light NL. The DBR structures are designed in such a way that they amplify the absorption of modulation light ML within the waveguide structure with the waveguides 11a, 11b to 11g, thereby improving the efficiency of charge carrier generation. In this context, the two planar DBR structures 31 and 31′ form a vertical cavity in which the modulation light ML is ideally reflected back and forth several times until it is essentially completely absorbed by the waveguide structure for the useful light.

An alternative embodiment is shown in FIG. 8, in which the planes of the waveguide structures for the use light NL and the waveguide structure for the modulation light ML are arranged as close as possible to each other. In this embodiment example, the distance between the waveguides 11a, 11b to 11g and the waveguides 21a, 21b to 21g for the modulation light is only a few 10 nm to a few 100 nm. As a result, the modulation light couples directly into the waveguide structure with the waveguides 11a, 11b to 11g by means of evanescent coupling and is at least partially absorbed there. This embodiment has the advantage that additional coupling structures 22 or DBR structures can generally be dispensed with, thus simplifying manufacture. However, a DBR structure below waveguides 11a, 11b to 11g is also possible here.

FIG. 9 now shows a further embodiment example with a different optical component compared to the previous embodiment examples. As already mentioned, the background to this is the fact that the basic principle of a refractive index change in optical components by additionally introducing modulation light is not limited to an optical phase array in the narrower sense. Rather, it is also possible, for example, to reduce the line width of an edge-emitting laser, to stabilize such a laser or to flexibly adjust other optical functionalities.

In the present embodiment example, as in the other embodiments, the optical component 30′ comprises a material 30 in which a waveguide 11 is embedded from a signal input to a signal output 12. The waveguide is used to feed and process the use light NL. A resonator element 32 is connected to the waveguide via an optical coupling D, whereby the element 32 in the present form is designed as a ring resonator. In an operation of this arrangement, a single mode of the scattered use light NL is selected, amplified and provided at the output 12 by the optical coupling D and the geometric parameters of the ring resonator 32. In this way, an edge-emitting laser diode can be stabilized against thermal fluctuations and its linewidth can be significantly reduced so that it is only a few megahertz.

Above or below this ring resonator 32, a further partially ring-shaped waveguide element 21 is now provided, at the end 33 of which a mirror or an absorbing element is arranged. An arrangement with a mirror has the advantage that unabsorbed light is reflected back into the curved waveguide 21 and can thus be absorbed again in the ring resonator. As in the other embodiments, the ring-shaped structure above the ring resonator also comprises a decoupling structure with which the modulation light ML provided by the laser diode 1 is radiated into the ring resonator and generates free charge carriers there. These cause a refractive index change in the ring resonator, whereby the selected mode is shifted by the optical coupling D. By modulating the intensity of the irradiated modulation light, the refractive index is changed and thus a frequency modulation of the scattered use light at output 12 is realized.

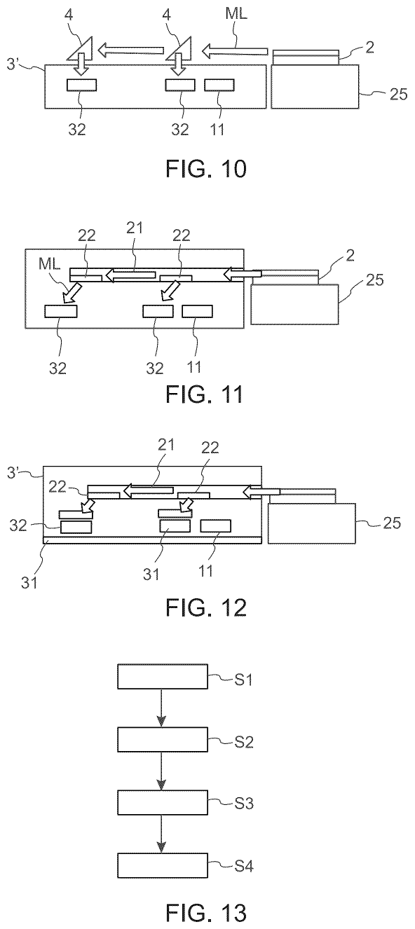

The proposed optical component can be implemented in various ways, particularly with regard to the supply of modulation light. FIGS. 10, 11 and 12 show various embodiments in this respect with their respective cross-sections. In FIG. 10, coupling into the ring resonator 32 is achieved by additional mirror elements 4, which are prism-shaped. For this purpose, the modulation light ML is provided by a laser device 2, which is arranged on an additional, laterally arranged carrier with the height of the optical element three′. Some of the modulation light is reflected in the prism-shaped mirror elements 4 and directed onto the ring resonator 32, while some of it continues out of the first element, enters the second mirror element 4 and is reflected there. This arrangement has the advantage that it can be easily mounted on existing optical components 3′, provided that the material forming the optical component is transparent to the modulation light.

FIG. 11 shows an alternative embodiment in which an additional waveguide structure 21 with several decoupling elements 22 is located above the plane of the ring resonator. These are used to decouple the modulation light ML in the waveguide structure 21 and direct it onto the waveguide of the ring resonator 32. Here too, the modulation light is generated by an externally arranged second laser diode 2.

Finally, in a third embodiment, the ring resonator is arranged between two DBR structures 31. One of the DBR structures below the ring resonator is designed as a flat mirror, while the second DBR structure above the ring resonator 32 merely covers the material of the ring resonator. Here too, a decoupling structure 22 serves to irradiate the light onto the DBR structure 31 and the material of the ring resonator.

The various implementations and design forms can be combined with their individual features in order to generate charge carriers in an optically relevant area by means of absorption of modulation light, thereby changing the refractive index within this material as explained above. This allows optical components with adjustable functionalities to be realized.

Finally, FIG. 13 shows an embodiment of a method for operating an optically adjustable component. In this component, a signal input is provided for feeding a use light of a first wavelength into at least one waveguide. In addition, there is a signal output at which an adjusted or adjustable use light can be tapped. The optical component comprises a material that is transparent to the useful light, which in turn comprises a first band gap or is designed in such a way that it absorbs light of less than a predetermined wavelength. Such an optical component is now provided in step S1 and connected to a first laser device for generating the useful light.

In addition, a second laser device is provided, which is designed to generate a modulation light. A photon energy of the modulation light is greater than the first band gap. In the proposed method, the use light is now irradiated into the first component in step S2 and processed in the desired manner in the optical component. The light processed in the component can be tapped at the output. In a second step S2, the modulation light is now also supplied in such a way that at least part of the modulation light is irradiated into the material of the area relevant for the optical component. As shown in the previous embodiment examples, the component can be a waveguide, a resonator, a PIC or PLC or even a waveguide array.

Due to the higher photon energy, the irradiated modulation light is now absorbed within this area and generates free charge carriers there. Depending on the intensity of the irradiated modulation light, an equilibrium is established between charge carrier recombination and charge carrier generation. However, the free charge carriers simultaneously change the refractive index of the material and thus influence the incident useful light. The intensity of the modulation light can be used to adjust this refractive index change over a predetermined range and thus also change the functionality of the optical component.

In this way, it is possible to effect a refractive index change in an optical component by purely optical means and thus influence its functionality. Depending on the application and design, this can be, for example, a phase shift, frequency modulation, optical switching or other functions. In contrast to other solutions, the refractive index change is essentially the intensity modulation of the modulation light and can therefore reach high speeds in the range of several 100 MHz. Furthermore, complex additional circuitry measures are reduced, only an additional laser device is required to generate the modulation light with a higher photon energy than the useful light.

1. An optical phase array, comprising:
a signal input for supplying use light of a first wavelength;
a first waveguide array with at least one signal output, which is connected to the signal input and comprises a material transparent to the use light and having a first band gap;
a first modulation input for supplying modulation light of a second wavelength; and
a second waveguide array connected to the first modulation input, which is arranged in the vicinity of the first waveguide array in such a way that modulation light can be conducted onto the first waveguide array, the first band gap being smaller than the energy of the modulation light.

2. The optical phase array according to claim 1, wherein the first waveguide array comprises a plurality of waveguides that lie substantially in a plane and comprise a defined time-of-flight difference from one another, optionally wherein the second waveguide array comprises a plurality of waveguides that lie substantially in a plane and comprise a defined time-of-flight difference from one another.

3. The optical phase array according to claim 1, wherein the first waveguide array is formed as or comprises at least one of the following elements:
an optical ring oscillator;
a Mach-Zehnder modulator; and
a directional optical coupler.

4. The optical phase array according to claim 1, wherein the first waveguide array and the second waveguide array are arranged one above the other in two substantially parallel planes.

5. The optical phase array according to claim 1, further comprising:
a second modulation input for supplying modulation light of the second or a third wavelength; and
a third waveguide array connected to the second modulation input and arranged in the vicinity of the first waveguide array in such a way that modulation light of the second or third wavelength can be transmitted to the first waveguide array, whereas the first band gap is smaller than the energy of the light of the third wavelength.

6. The optical phase array according to claim 5, wherein the first waveguide array is disposed between the second and third waveguide arrays.

7. The optical phase array according to claim 5, wherein the second waveguide array comprises a plurality of waveguides lying substantially in a plane and comprising a defined time-of-flight difference with respect to each other.

8. The optical phase array according to claim 5, wherein the second and third waveguide arrays at least partially overlap; and/or are arranged in mirror image.

9. The optical phase array according to claim 1, wherein the second and/or third waveguide array comprises an output coupling structure, in particular in the form of diffractive optics, which faces the first waveguide array.

10. The optical phase array according to claim 1, wherein the second and/or third waveguide array comprises a distance from the first waveguide array of less than 300 nm and in particular less than 100 nm, and in particular comprises a distance smaller than the wavelength of the modulation light and in particular a distance smaller than half the wavelength of the modulation light.

11. The optical phase array according to claim 1, wherein the transit time differences in the waveguides of the first, second and/or third waveguide array are formed by different lengths of the waveguides.

12. The optical phase array according to claim 1, further comprising
a particularly planar DBR structure, which is arranged on the side of the first waveguide array opposite the second waveguide, in particular for the back reflection of modulation light.

13. The optical phase array according to claim 1, further comprising
a distribution layer, in particular a planar distribution layer, which is arranged on the side of the first waveguide opposite the second waveguide and is designed to reflect modulation light back or to distribute charge carriers generated by modulation light in the first waveguide array.

14. The optical phase array according to claim 1, wherein the material of the first waveguide array comprises at least one of the following components:
InP;
Si;
GaAs;
AlGaAs;
AlGaP;
and GaN;
and/or the material of the second and/or third waveguide array comprises at least one of the following components:
AlN;
SiN_{X};
Al2O3; and
SiO2.

15. A resonator assembly, comprising:
a waveguide that connects a signal input for supplying use light of a first wavelength to a signal output;
a resonator, in particular a ring resonator, which is optically coupled to the waveguide in order to amplify a frequency mode of the use light in the waveguide; and
an arrangement placed above the resonator, which is designed to couple modulation light of a second wavelength into the resonator; wherein
the resonator comprises a material with a band gap so that the resonator is essentially transparent for use light and absorbs modulation light by forming charge carriers.

16. The resonator assembly according to claim 15, wherein the arrangement placed above the resonator comprises one or more deflecting mirrors; or wherein the arrangement comprises a second waveguide having diffractive optics configured to direct modulation light in the second waveguide onto the resonator.

17. The resonator assembly according to claim 15, further comprising
a particularly planar DBR structure, which is arranged on the side of the resonator opposite the second waveguide, in particular for the back reflection of modulation light.

18. (canceled)

19. A method of operating an optical phase array, the phase array comprising a signal input for supplying use light of a first wavelength and a first waveguide array having at least one signal output connected to the signal input and comprising a material transparent to the use light and having a first bandgap, the method comprising:
irradiating a use light into the first waveguide array;
irradiating a modulation light in such a way that at least part of the modulation light is coupled into the first waveguide array; and
generating charge carriers in the first waveguide array by absorption of the coupled modulation light.

20. The method according to claim 19, in which the modulation light is irradiated by means of a second waveguide array which is arranged in the vicinity of the first waveguide array in such a way that modulation light can be guided onto the first waveguide array.

21. The method according to claim 19, wherein first waveguide array comprises a plurality of waveguides lying substantially in one plane and comprising a defined time-of-flight difference with respect to each other, optionally wherein the second waveguide array comprises a plurality of waveguides lying substantially in one plane and comprising a defined time-of-flight difference with respect to each other.

22. The method according to claim 21, in which transit time differences in the waveguides of the first, second and/or third waveguide array are caused by different lengths of the waveguides.
